(19) United States
(12) Patent Application Publication
(10) Pub. No.: US 2015/0364454 A1
(43) Pub. Date: Dec. 17, 2015

(54) RECONFIGURED WIDE I/O MEMORY MODULES AND PACKAGE ARCHITECTURES USING SAME

(71) Applicant: Apple Inc., Cupertino, CA (US)

(72) Inventors: Jun Zhai, San Jose, CA (US); Chonghua Zhong, Cupertino, CA (US); Kunzhong Hu, Cupertino, CA (US); Se Young Yang, San Jose, CA (US)

(21) Appl. No.: 14/558,906

(22) Filed: Dec. 3, 2014

Related U.S. Application Data
(60) Provisional application No. 62/011,832, filed on Jun. 13, 2014.
(60) Provisional application No. 62/011,827, filed on Jun. 13, 2014.

(51) Int. Cl. H01L 25/18; H01L 23/00; H01L 23/528; H01L 23/31; H01L 23/367; H01L 25/065; H01L 23/522

(52) U.S. Cl. CPC H01L 25/18; H01L 25/0655; H01L 24/09; H01L 24/17; H01L 23/5226; H01L 23/3157; H01L 23/367; H01L 23/528; H01L 2924/381; H01L 2924/38; H01L 2224/02379; H01L 2224/02381; H01L 2224/02375; H01L 2224/02372; H01L 2224/16146; H01L 2224/16235; H01L 2924/182; H01L 2924/15331; H01L 2924/152; H01L 2924/1436

(57) ABSTRACT

In some embodiments, it is desirable to increase memory bandwidth using an integrated solution. In one embodiment, wide I/O memory may be used. Described herein are embodiments of systems and methods of reconfiguring wide I/O memory modules. The reconfigured memory modules may be configured such that the memory modules function in combination with current packaging architectures.

### CLAIM OF PRIORITY

This application claims benefit of priority of U.S. Provisional Application Ser. No. 62/011,832 entitled “RECONFIGURED WIDE I/O Memory MODULES” filed Jun. 13, 2014, and U.S. Provisional Application Ser. No. 62/011,827 entitled “PACKAGE ARCHITECTURES WITH RECONFIGURED WIDE I/O MEMORY” filed Jun. 13, 2014, the content of which is incorporated by reference herein in its entirety and for all purposes.

### BACKGROUND

1. Technical Field

Embodiments described herein relate to semiconductor packaging and methods for packaging semiconductor devices. More particularly, some embodiments disclosed herein relate to adapted package architectures to wide I/O memory modules.

2. Description of the Related Art

The standard for wide I/O (e.g., for mobile DRAM, released in early 2012) uses through-silicon vias (TSVs) to connect DRAM to logic on three-dimensional integrated circuits. With its 512-bit data interface, wide I/O Single Data Rate (SDR) doubles the bandwidth of the Low-Power Double Data Rate 2 specification without significantly increasing power consumption.

Devices that use TSV connections between homogeneous die are already available. Wide I/O is pressing the need for TSV connections between heterogeneous die. With known homogeneous TSV connections there are claims of a hundredfold improvement in die-to-die connectivity bandwidth per watt with one-fifth the latency.

The full potential of TSV technology comes with the ability to connect die with different physical properties. Though it is possible to put logic, memory, radio-frequency (RF), analog, power, and image-sensing circuits all on the same piece of silicon, it may be preferable to put them on separate die for the best performance at the lowest cost.

The wide I/O standard takes full advantage of 3-D die stacking by significantly improving performance and power. By using low-speed low-capacitance connections, wide I/O transmits data at about half the power per bit of some currently used standards. For example wide I/O would double the bandwidth at the same power as many current standards with no impact on the mass or volume of a cellular phone.

Unfortunately TSV technology has developed slower than expected and while wide I/O is fully developed TSV technology has not kept pace. This has led to problems with how to take advantage of wide I/O technology until that day when TSV technology has developed enough to take advantage of it.

### SUMMARY

In some embodiments, it is desirable to increase memory bandwidth using an integrated solution. In one embodiment, wide I/O memory may be used. Described herein are embodiments of systems and methods of reconfiguring wide I/O memory modules. The reconfigured memory modules may be configured such that the memory modules function in combination with current or new packaging architectures.

### BRIEF DESCRIPTION OF THE DRAWINGS

The following detailed description makes reference to the accompanying drawings, which are now briefly described.

FIG. 1 depicts an embodiment of a standard wide I/O memory module including four channels.

FIG. 2 depicts an embodiment of two relatively smaller wide I/O memory modules including two channels each positioned towards an edge of the module.

FIG. 3 depicts an embodiment of a wide I/O memory module including four channels with two channels flipped out towards the edges.

FIGS. 4A-B depict an embodiment of a standard wide I/O memory module including four channels with a post fabrication redistribution layer (RDL) coupled to the module.

FIGS. 5A-B depict an embodiment of a standard wide I/O memory module including four channels with a Fanout Wafer Level Package (FOWLP) including a RDL coupled to the module.

FIG. 6 depicts an embodiment of two relatively smaller wide I/O memory modules including two channels each positioned towards an edge of the module combined with a RDL coupled to the modules.

FIG. 7 depicts an embodiment of two relatively smaller wide I/O memory modules including two channels each positioned towards an edge of the module combined with a FOWLP including an RDL coupled to the modules.

FIG. 8 depicts an embodiment of a package with multiple split wide I/O memory modules coupled to the package using a redistribution layer (RDL).

FIG. 9 depicts an embodiment of a package with multiple split wide I/O memory modules coupled to the package using silicon interposers or PCB bar positioned in the package.

FIGS. 10A-B depict embodiments of a package with multiple wide I/O memory modules configured in a Fanout Wafer Level Package (FOWLP) including an RDL used to couple the wide I/O memory modules to the package.

FIG. 11 depicts an embodiment of a package with a wide I/O memory module configured in a FOWLP including an RDL used to couple the wide I/O memory module to the package.

FIG. 12 depicts an embodiment of a package with a wide I/O memory module, including a post fabrication RDL coupled to the package with vias through an encapsulant.

FIG. 13 depicts an embodiment of a package with a wide I/O memory module, coupled to an underside of the package through the package's RDL.

FIG. 14 depicts an embodiment of a package including a die and multiple split wide I/O memory modules coupled to a heterogeneous RDL.

FIG. 15 depicts an embodiment of a package with a wide I/O memory module, including a post fabrication RDL.

FIG. 16 depicts an embodiment of a package including a die and multiple split wide I/O memory modules coupled to the die using a silicon bridge positioned between the package RDL and the die and memory modules.

FIG. 17 depicts an embodiment of a package including a die and multiple split wide I/O memory modules coupled to the die using a silicon bridge positioned on an opposing side of the package RDL from the die and memory modules.

FIG. 18 depicts an embodiment of a package including a die and a memory module coupled to the die using a post fabrication RDL.

Specific embodiments are shown by way of example in the drawings and will be described herein in detail. It should be understood, however, that the drawings and detailed description are not intended to limit the claims to the particular embodiments disclosed, even where only a single embodiment is described with respect to a particular feature. On the contrary, the intention is to cover all modifications, equivalents and alternatives that would be apparent to a person skilled in the art having the benefit of this disclosure. Examples of features provided in the disclosure are intended to be illustrative rather than restrictive unless stated otherwise.

The headings used herein are for organizational purposes only and are not meant to be used to limit the scope of the description. As used throughout this application, the word “may” is used in a permissive sense (i.e., meaning having the potential to), rather than the mandatory sense (i.e., meaning must). The words “include,” “including,” and “includes” indicate open-ended relationships and therefore mean including, but not limited to. Similarly, the words “have,” “having,” and “has” also indicated open-ended relationships, and thus mean having, but not limited to. The terms “first,” “second,” “third,” and so forth as used herein are used as labels for nouns that they precede, and do not imply any type of ordering (e.g., spatial, temporal, logical, etc.) unless such an ordering is otherwise explicitly indicated. For example, a “third die electrically connected to the module substrate” does not preclude scenarios in which a “fourth die electrically connected to the module substrate” is connected prior to the third die, unless otherwise specified. Similarly, a “second” feature does not require that a “first” feature be implemented prior to the “second” feature, unless otherwise specified.

Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.

Various components may be described as performing a task or tasks, for convenience in the description. Such descriptions should be interpreted as including the phrase “configured to.” Reciting a component that is configured to perform one or more tasks is expressly intended not to invoke 35 U.S.C. §112 paragraph (f), interpretation for that component.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

### DETAILED DESCRIPTION OF EMBODIMENTS

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

In some embodiments, it is desirable to increase memory bandwidth using an integrated solution. In one embodiment, wide I/O memory may be used. Described herein are embodiments of systems and methods of reconfiguring wide I/O memory modules. The reconfigured memory modules may be configured such that the memory modules function in combination with current packaging architectures. In some embodiments, a standard wide I/O memory module may comprise a set of electrical conductors substantially centered within the memory module away from the edges. In some embodiments, a standard wide I/O memory module may comprise a set of electrical conductors configured in at least four channels. In some embodiments, reconfigured wide I/O memory modules may be formed such that they are smaller than standard wide I/O memory modules. In some embodiments, a reconfigured wide I/O memory module may comprise a set of electrical conductors positioned substantially along the edges. In some embodiments, reconfigured wide I/O memory modules may comprise a set of electrical conductors configured in at least two channels. In some embodiments, reconfigured wide I/O memory modules may include any design, structure, process change to the existing memory die/wafer to in order to change the memory modules pad (or bump) locations and/or pitch, number of channels, and/or die size. In some embodiments, wide I/O herein may refer to wide I/O or wide I/O2 or wide I/O3 as defined by JEDEC solid state technology association standards and publications.

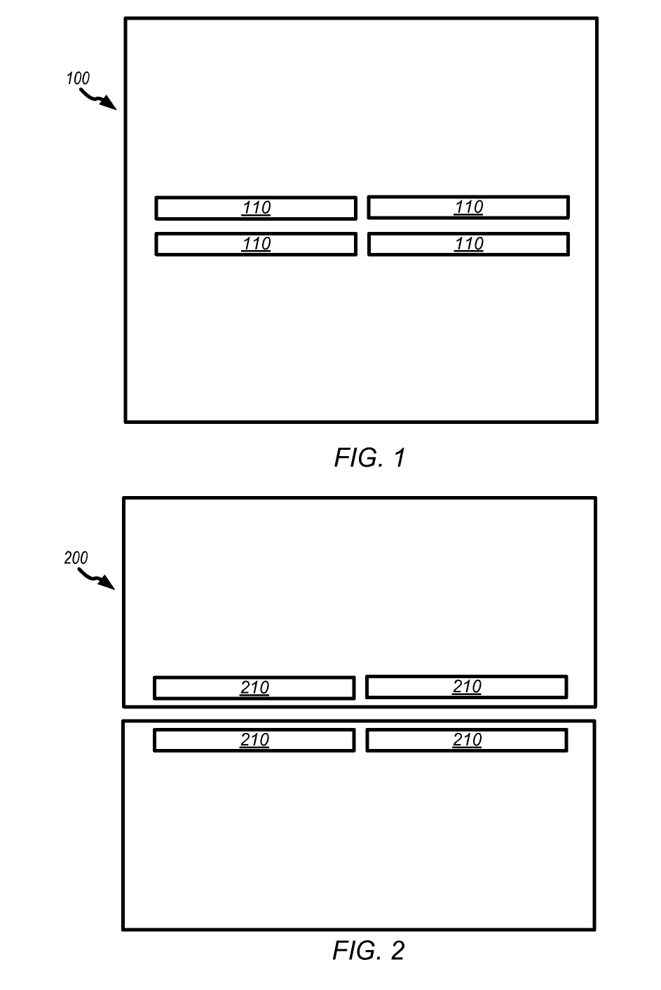

FIG. 1 depicts an embodiment of a standard wide I/O memory module 100 including four channels 110. The four channels may include different groupings of electrical connectors. The electrical connectors may be used to electrically connect the memory module 100 to other electrical components. However, this type of standard configuration was designed for use with TSVs in a stacked three-dimensional package architecture. As mentioned TSV has yet to mature as a viable technology. One problem with, for example, the standard memory configuration depicted in FIG. 1 is the long channel length configuration of the electrical contacts for use with non TSV based current architectures. One problem with, for example, the standard memory configuration depicted in FIG. 1 is the centered configuration of the electrical contacts for use with non TSV based current architectures. In response to at least these problems reconfigured wide I/O memory modules may be formed as smaller units to give flexibility to properly place the reconfigured units in module to reduce channel length of the electrical contacts facilitating the electrical coupling of the memory modules to other electrical components as well as improving system signal integrity (SI) performance. The reconfigured memory modules may include one or more channels of electrical conductors positioned adjacent one or more edges of the memory module. FIG. 2 depicts an embodiment of two reconfigured relatively smaller wide I/O memory modules 200 including two channels 210 each positioned towards an edge of the module.

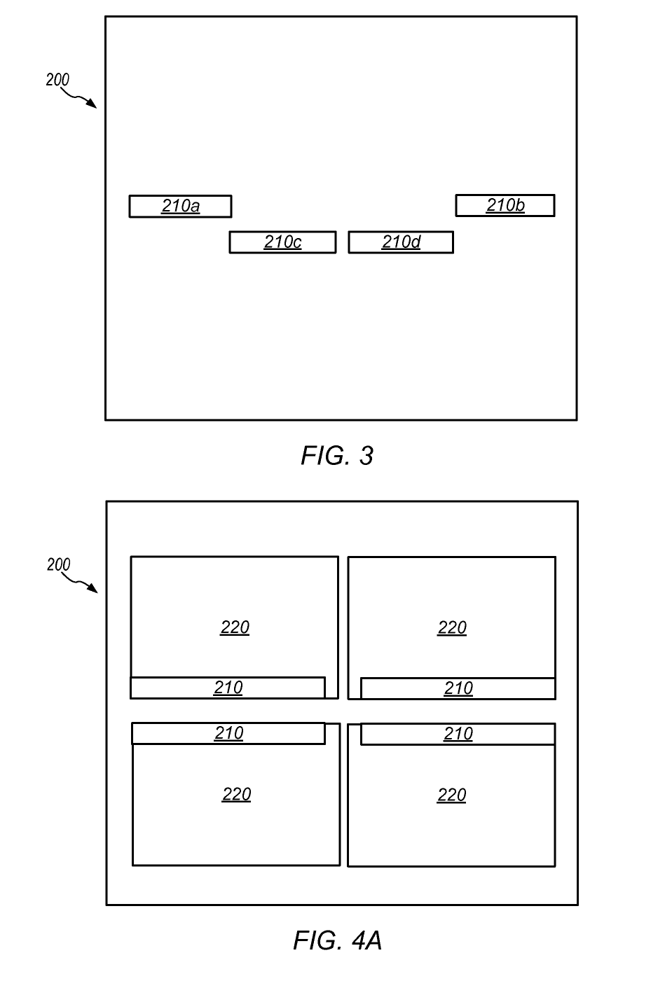

Current electrical contact/channel configuration of wide I/O memory modules may prove limiting for package SI performance in part due to its IO locations and in part due to fine IO pitch (˜40-60 um) which may limit fanout configurations. In some embodiments, a reconfigured wide I/O memory module may reposition channels of electrical contacts to reduce congestion and free up routing paths between the reconfigured memory module and other electronic components. FIG. 3 depicts an embodiment of a reconfigured wide I/O memory module 200 including four channels 210a-d with two channels 210a-b flipped out towards the edges of the memory module.

In some embodiments, a post fabricated substrate (e.g., RDL) may be used to reposition the IO pads to improve SI performance and increase the bump pitch of the wide I/O memory module (e.g., from ˜40 um to ˜80 um) for routing flexibility. FIGS. 4A-B depict an embodiment of a reconfigured wide I/O memory module including four channels with a post fabrication RDL 220 for each channel 210 coupled to the memory module. The pitch of the memory module 200 may be increased using the RDL 220 and the RDL's larger pitched set of electrical conductors 240. Electrical conductors 240 may be optional in some embodiments.

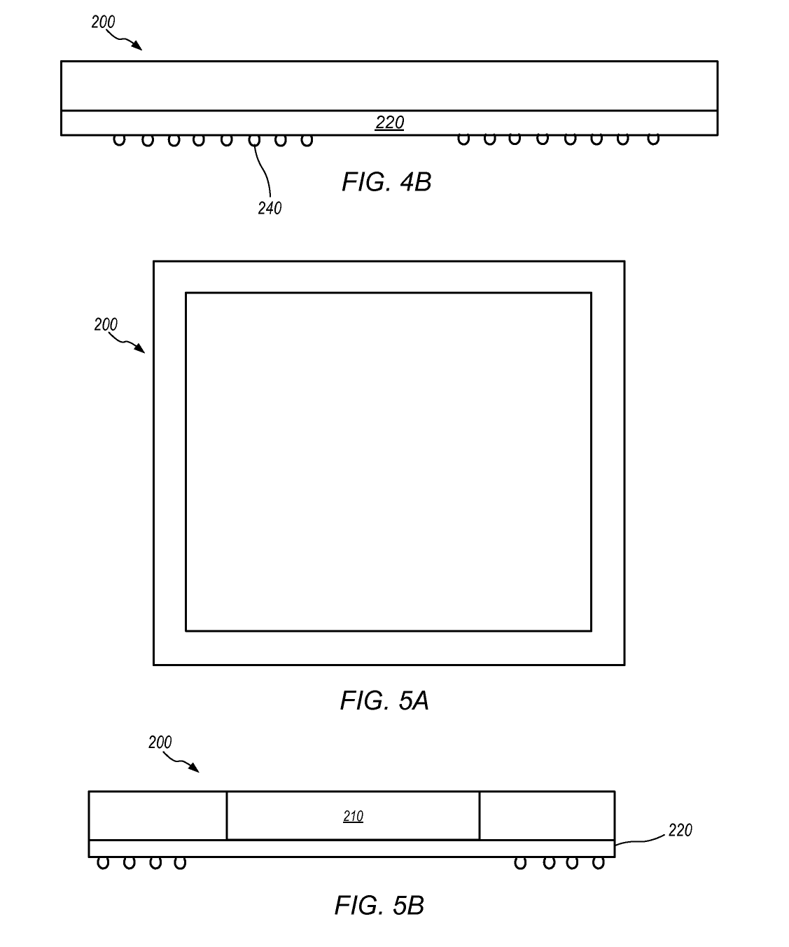

In some embodiments, a fan out wafer level technology (e.g., FOWLP) may be used to redistribute the I/Os of standard Wide I/O or reconfigured Wide I/O such as that shown in FIG. 2 to locations convenient for PoP package routing as well as increase the bump pitch of the wide I/O memory module (e.g., from ˜40 um to ˜80 um). The substrate may electrically connect the electrical connectors in the memory module to the electrical connectors of the substrate positioned around the edge. FIGS. 5A-B depict an embodiment of a standard wide I/O memory module 200 including four channels 210 including a substrate 220 (e.g., FOWLP including a RDL) coupled to the module.

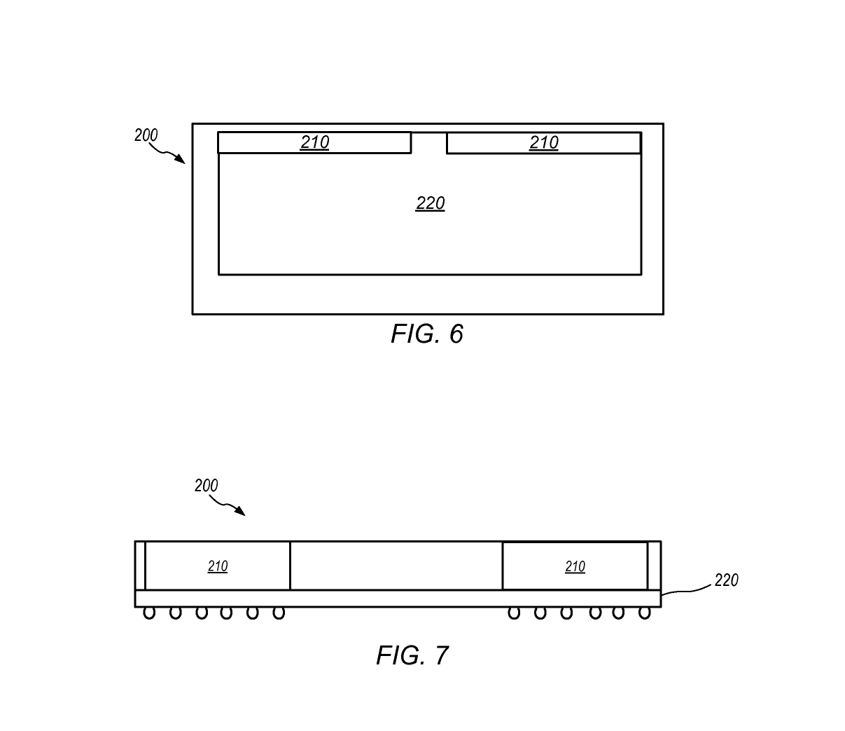

Several different strategies have been disclosed herein dedicated to reconfiguring standard wide I/O memory modules to better function with current non TSV package architectures. In some embodiments, multiple different embodiments may be combined in a single embodiment to further increase the efficiency of an electronic component employing a reconfigured memory module. (FIG. 6 needs to be revised to make it more representative) FIG. 6 depicts an embodiment of one relatively smaller wide I/O memory modules 200 including two or more channels 210 each positioned towards an edge of the module combined with a RDL 220 coupled to the modules. FIG. 7 depicts an embodiment of two relatively smaller wide I/O memory modules 200 including two or more channels 210 each positioned towards an edge of the module combined with a FOWLP including an RDL 220 coupled to the modules.

FIG. 8 depicts an embodiment of a semiconductor device package assembly 1100 including a die 1110 and a substrate 1120. In some embodiments, the substrate 1120 may include what is commonly referred to as a redistribution layer (RDL). The substrate 1120 may include a first set of electrical conductors 1130 coupled to a first surface 1140 of the substrate. The first set of electrical conductors 1130 may be configured to electrically connect the semiconductor device package assembly 1100. The die 1110 may be electrically connected to a second surface 1150 of the substrate 1120 using a second set of electrical conductors 1160. In some embodiments, electrical conductors 1160 may be optional, or they may be part of the substrate 1120. In some embodiments, the second surface 1150 may be substantially opposed to the first surface 1140 of the substrate 1120. The assembly 1100 may include at least one reconfigured wide I/O memory module 1170. In some embodiments, the reconfigured memory module may include electrical conductors positioned towards the edge of the module. The memory module 1170 may be positioned in a plane substantially above the die 1110. In some embodiments, the memory modules 1170 may be coupled to the substrate 1120 using vias 1180. In some embodiments, the reconfigured memory modules 1170 may include a substrate (e.g., a post fabrication RDL, not shown in the drawing). The substrate may couple the memory modules 1170 to the vias 1180 through bumps or balls and subsequently to the substrate 1120. In some embodiments, the reconfigured memory module 1170 maybe a FOWLP. In some embodiments mechanical bumps or balls maybe added to module 1170 for mechanical balance. There may be underfill 1122 to protect the solder bumps and memory modules 1170. The substrate may convert the pitch (e.g., ˜40 um) of the electrical conductors of the memory modules 1170 to the pitch (e.g., ˜80 um) of the vias 1180. The vias 1180 may connect the memory module 1170 to the substrate 1120 through an encapsulant 1190. Die 1110 may be exposed, or fully embedded in encapsulant 1190. In some embodiments, the assembly 1100 may include silicon spacer/heat spreader 1200.

In some embodiments, the underfill 1122 may include an electrically insulating material. The electrically insulating material may include a dielectric polymer. In some embodiments, the method may include inhibiting deformation of the semiconductor device package assembly using the dielectric polymer.

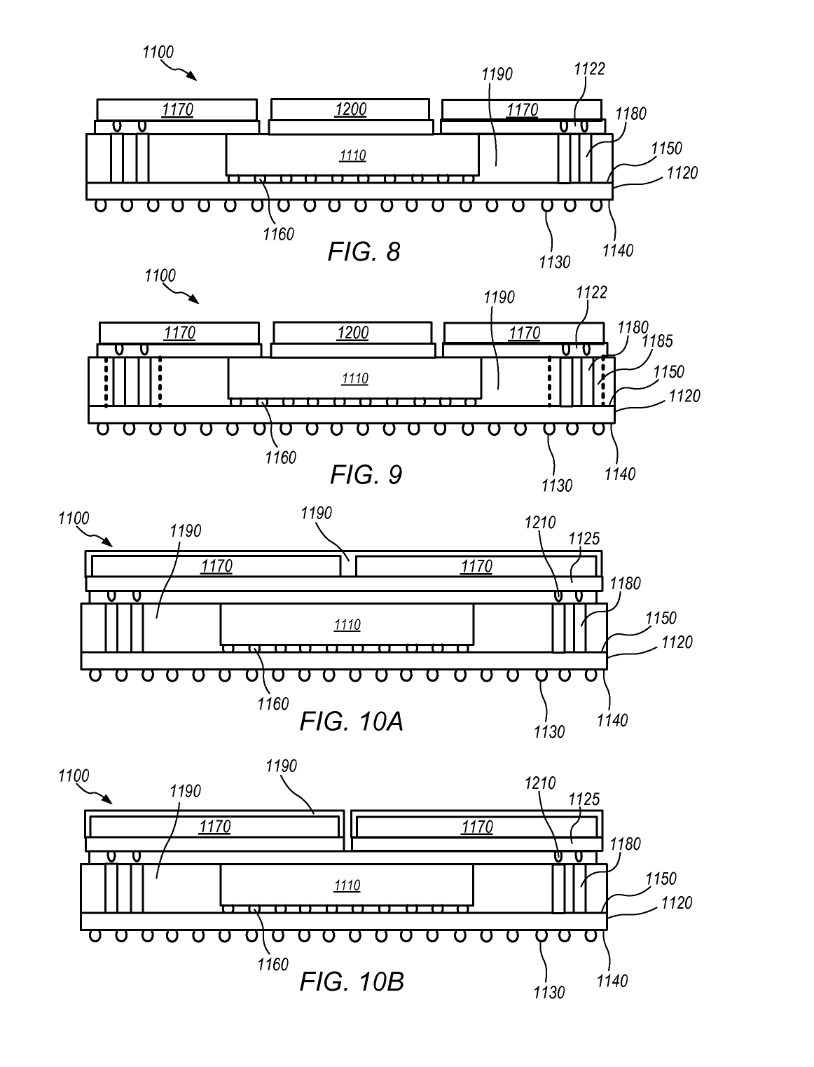

In some embodiments, the memory module 1170 may be coupled to the substrate 1120 using vias 1180. The vias 1180 may include a pitch (e.g., ˜40 um) which is substantially equivalent to the pitch of the electrical conductors of the memory module 1170. The vias 1180 may connect the memory module 1170 to the substrate 1120 through a silicon interposer or a PCB bar 1185 positioned in an encapsulant 1190. In some embodiments, the assembly 1100 may include silicon spacer/heat spreader 1200. FIG. 9 depicts an embodiment of a package with multiple split wide I/O memory modules 1170 coupled to the package using silicon interposers 1185 positioned in the package 1100.

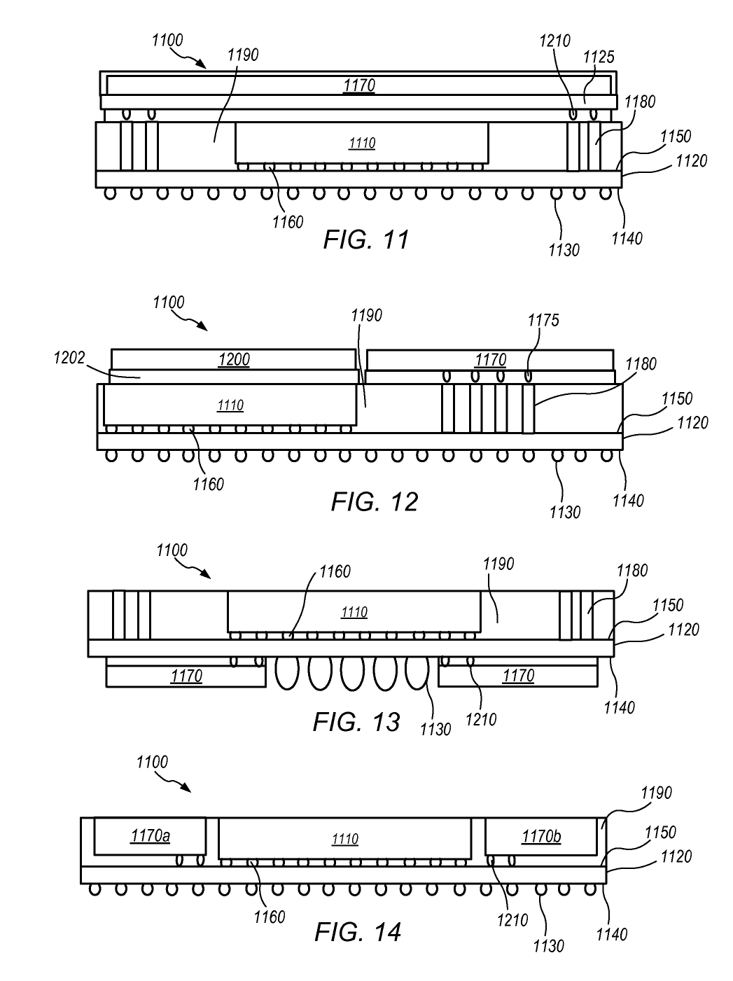

In some embodiments, one or more reconfigured wide I/O memory modules 1170 may be coupled to a die 1110 using a FOWLP including a substrate 1125 (e.g., RDL) and a third set of electrical conductors 1210 used to couple the wide I/O memory modules to the die. FIGS. 10A-B depict embodiments of a package 1100 with multiple split wide I/O memory modules 1170 configured in a FOWLP including an RDL 1125 used to couple the wide I/O memory modules to the die. FIG. 11 depicts an embodiment of a package 1100 with a wide I/O memory module 1170 configured in a FOWLP including an RDL 1125 used to couple the wide I/O memory module to the die. The substrate 1125 may couple the memory modules 1170 to the vias 1180 and subsequently to the substrate 1120. The substrate 1125 may convert the pitch (e.g., ˜40 um) of the electrical conductors of the memory modules 1170 to the pitch (e.g., ˜80 um) of the vias 1180. The vias 1180 may connect the memory module 1170 to the substrate 1120 through an encapsulant 1190. The memory modules 1170 may be at least substantially encased in an encapsulant 1190 covering both memory modules 1170 separately (e.g., as depicted in FIG. 10A) or covering the entire surface in addition to the memory modules 1170 (e.g., as depicted in FIG. 10B).

FIG. 12 depicts an embodiment of a package 1100 with a wide I/O memory module 1170, including a substrate 1120 coupled to the package with vias through an encapsulant 1190. In some embodiments, the substrate 1120 may include what is commonly referred to as a post fabrication RDL 1120. The substrate 1120 may include a first set of electrical conductors 1130 coupled to a first surface 1140 of the substrate. The first set of electrical conductors 1130 may be configured to electrically connect the semiconductor device package assembly 1100. The die 1110 may be electrically connected to a second surface 1150 of the substrate 1120 using a second set of electrical conductors 1160. Electrical conductors 1160 may be part of the substrate 1120. The assembly 1100 may include a wide I/O memory module 1170. The memory module 1170 may include a post Fab RDL layer which fans out the pad pitch from a smaller pitch (˜40 um) to a larger pitch (˜80 um). The memory module 1170 may be positioned in a plane substantially above the die 1110. In some embodiments, the memory module 1170 may be coupled to the substrate 1120 using vias 1180. The vias 1180 may include a pitch (e.g., ˜80 um) which is substantially equivalent to the pitch of the electrical conductors 1175 of the memory module 1170. The vias 1180 may connect the memory module 1170 to the substrate 1120 through an encapsulant 1190. In some embodiments, the assembly 1100 may include silicon spacer/heat spreader 1200. Silicon spacer or heat spreader 1200 maybe attached to the package through epoxy or thermal interface material 1202.

FIG. 13 depicts an embodiment of a package 1100 with a wide I/O memory module 1170, coupled to a first side 1140 of the substrate 1120 through the package's substrate 1120 (e.g., RDL). In some embodiments, memory module 1170 may include at least two smaller memory modules including electrical conductors 1210 positioned towards an edge of the memory module as depicted in FIG. 13 (e.g., decreasing connection distances between the memory modules and the die). In some embodiments, the package 1100 may include optional vias 1180. The vias 1180 may be configured to a second package to the package 1100 in a package on package configuration. The vias 1180 may be positioned in an encapsulant 1190.

FIG. 14 depicts an embodiment of a package 1100 including a die 1110 and multiple reconfigured wide I/O memory modules 1170 coupled to a substrate 1120. In some embodiments, the substrate 1120 may include what is commonly referred to as a heterogeneous RDL. The substrate 1120 may include a first set of electrical conductors 1130 coupled to a first surface 1140 of the substrate. The first set of electrical conductors 1130 may be configured to electrically connect the semiconductor device package assembly 1100. The die 1110 may be electrically connected to a second surface 1150 of the substrate 1120 using a second set of electrical conductors 1160. In some embodiments, the second surface 1150 may be substantially opposed to the first surface 1140 of the substrate 1120. The assembly 1100 may include multiple reconfigured wide I/O memory modules 1170a-b. The memory modules 1170 may be electrically coupled to the substrate 1120 using a third set of electrical conductors 1210. The die 1110 and the memory modules 1170 may be positioned adjacent one another on the substrate 1120. The die 1110 and the memory module 1170 may be at least substantially encased in an encapsulant 1190.

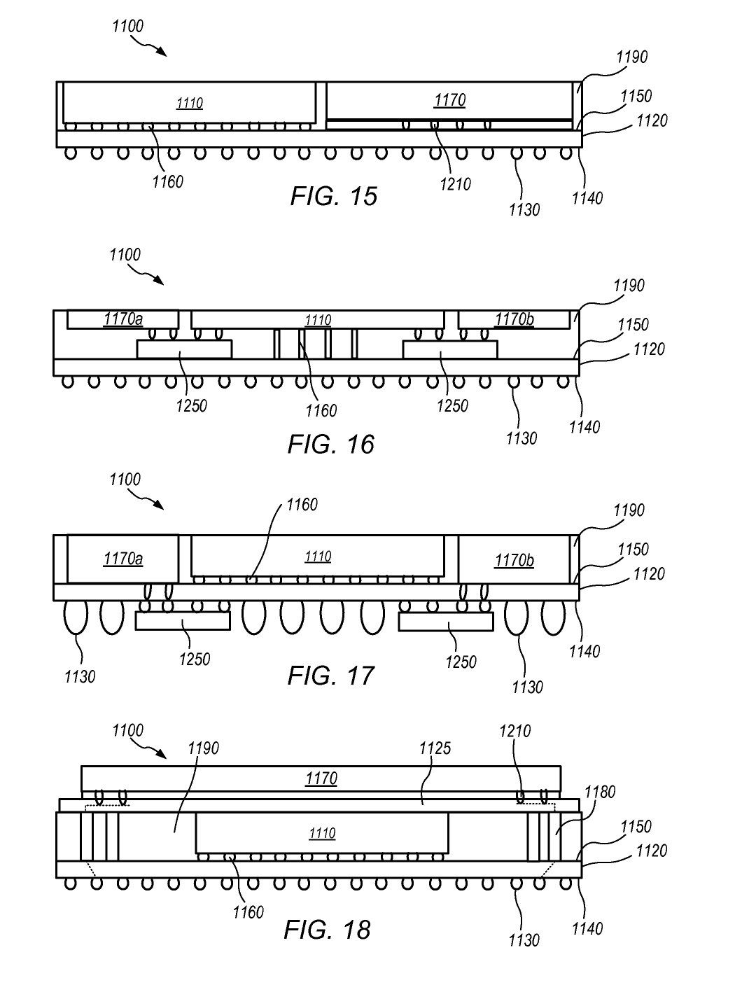

FIG. 15 depicts an embodiment of a package 1100 with a wide I/O memory module, including a substrate 1120. In some embodiments, the substrate 1120 may include a heterogeneous RDL. In some embodiments, memory module 1170 may contain a post Fab RDL layer (not shown in drawing). Electrical conductors 1160 and 1210 may be optional or may be part of the substrate 1120.

In some embodiments, reconfigured memory modules 1170 may be electrically coupled to a die 1110 using a silicon bridge 1250. The silicon bridge may be configured to connect of the I/O pads of the memory module to the I/O pads of die 1110. FIG. 16 depicts an embodiment of a package 1100 including a die 1110 and multiple reconfigured wide I/O memory modules 1170 coupled to the die using a silicon bridge 1250 positioned between the package substrate 1120 and the die 1110 and memory modules 1170. FIG. 17 depicts an embodiment of a package 1100 including a die 1110 and multiple reconfigured wide I/O memory modules 1170a-b coupled to the die 1110 using a silicon bridge 1250 positioned on an opposing side of the package substrate 1120 from the die 1110 and memory modules 1170.

In some embodiments, a silicon bridge 1250 is a piece of silicon formed from a larger silicon wafer. For example, a silicon wafer may be processed (e.g, patterned) to form a plurality of patterns of connection lines with each pattern corresponding to an individual silicon bridge. The silicon wafer may then be separated (e.g., diced) to produce a plurality of silicon bridges with each bridge containing one pattern of connection lines. In some embodiments, a silicon bridge 1250 may be formed at least in part from materials other than silicon. A bridge may be formed from a substrate material.

In some embodiments, a silicon bridge 1250 is coupled to die 1110 and memory module 1170 with electrical connectors. In certain embodiments, electrical connectors include solder interconnections. In some embodiments, electrical connectors include copper or gold interconnections. The patterned connections in a silicon bridge 1250 may have a very fine interconnect trace pitch. For example, traces may have an interconnect pitch of at most about 1 μm. In some embodiments, traces have an interconnect pitch of between about 0.5 μm and about 1 μm, between about 0.25 μm and about 1 μm, or between about 0.1 μm and about 1 μm.

FIG. 18 depicts an embodiment of a package 1100 including a die 1110 and a memory module 1170 coupled to the die using a post fabrication RDL 1125. In some embodiments, the memory module may include a wide I/O memory or a DDR memory. The memory module 1170 bump pitch may be increased to 80 um through a post fabrication RDL. A DDR memory module may be coupled to package 1100 or a wide I/O die package on package may be coupled to package 1100 using RDL 1125 and vias 1180.

Numerous variations and modifications will become apparent to those skilled in the art once the above disclosure is fully appreciated. It is intended that the following claims be interpreted to embrace all such variations and modifications.

What is claimed is:

1. A memory module, comprising:
a memory module comprising memory and at least two channels positioned adjacent an edge of the memory module, wherein each channel comprises a set of electrical connectors on which an independent interface interacts with respective subsections of the memory.

2. The memory module of claim 1, wherein the channels are electrically coupled to a substrate configured to adjust the pitch and/or position of the channels relative to the memory module.

3. The memory module of claim 1, wherein the at least two channels are positioned adjacent a single edge of the memory module.

4. The memory module of claim 1, wherein the at least two channels are positioned adjacent the edge of the memory module such that a longitudinal axis of each channel are substantially parallel to the edge.

5. The memory module of claim 1, wherein at least two of the channels are positioned adjacent the edge of the memory module such that a lateral axis of the channels are substantially parallel to the edge.

6. The memory module of claim 1, wherein the memory module comprises at least four channels such that a lateral axis of at least two of the channels are substantially parallel to the edge, and wherein the at least four channels are not positioned adjacent each other along a longitudinal axis of each channel.

7. The memory module of claim 1, wherein the memory module further comprises a redistribution layer coupled to at least one of the channels.

8. The memory module of claim 1, wherein the memory module further comprises a second substrate coupled to at least one of the channels, and wherein the redistribution layer is configured to increase a pitch of electrical connectors of the at least one channel.

9. The memory module of claim 1, wherein the memory module further comprises a second substrate coupled to a first channel of at least one of the channels, and wherein the redistribution layer is configured to increase a distance of electrical connectors of the at least one channel from electrical connectors of a second channel.

10. A semiconductor device package assembly, comprising:
a first package assembly comprising:
a first substrate comprising a first set of electrical conductors coupled to a first surface and configured to electrically connect the semiconductor device package assembly; and
a first die comprising a third surface electrically coupled to a second surface of the first substrate opposite to the first surface of the first substrate; and
at least one memory module comprising memory and at least two channels positioned adjacent an edge of the memory module, wherein each channel comprises a set of electrical connectors on which an independent interface interacts with respective subsections of the memory, wherein the memory module is coupled to a fourth surface of the first die of the first package assembly, wherein the fourth surface is opposite to the third surface of the die.

11. The semiconductor device package assembly of claim 10, wherein the at least one memory module is coupled to the first substrate using vias.

12. The semiconductor device package assembly of claim 10, wherein the at least one memory module comprises a second substrate electrically coupling the at least one memory module to the first substrate through vias.

13. The semiconductor device package assembly of claim 12, wherein the vias electrically connect the memory module to the first substrate through an electrically insulating material.

14. The semiconductor device package assembly of claim 12, further comprising a second set of electrical conductors electrically coupling the second substrate to the vias.

15. The semiconductor device package assembly of claim 13, wherein the second substrate converts a pitch of the second set of electrical conductors of the memory module to a pitch of the vias.

16. The semiconductor device package assembly of claim 10, further comprising an electrically insulating material coupling the memory module to the first package assembly.

17. The semiconductor device package assembly of claim 10, further comprising at least two memory modules, wherein the at least two memory modules are coupled to the fourth surface of the first die of the first package assembly.

18. The semiconductor device package assembly of claim 17, further comprising a spacer coupled to the fourth surface and positioned between at least two of the memory modules.

19. The semiconductor device package assembly of claim 17, further comprising a heat spreader coupled to the fourth surface and positioned between at least two of the memory modules.

20. The semiconductor device package assembly of claim 10, wherein the at least two channels are positioned adjacent the edge of the memory module such that a longitudinal axis of each channel are substantially parallel to the edge.
